(19) United States
(12) Patent Application Publication
(10) Pub. No.: US 2003/0168942 A1
(43) Pub. Date: Sep. 11, 2003

(54) Piezoelectric actuator and electronic device having the same

(76) Inventors: Akihiro Iino, Chiba-shi (JP); Masao Kasuga, Chiba-shi (JP); Satoshi Watanabe, Chiba-shi (JP)

Correspondence Address: ADAMS & WILKS, 31st Floor, 50 Broadway, New York, NY, 10004, US

(21) Appl. No.: 10/339,070

(22) Filed: Jan. 9, 2003

(30) Foreign Application Priority Data
Jan. 16, 2002 (JP) 2002-007788

(51) Int. Cl. H01L 41/18

(52) U.S. Cl. 310/331

(57) ABSTRACT

To provide an actuator that has a compact structure and a large driving force and is not affected by a disturbance such as vibrations and environmental conditions such as temperature or humidity. A piezoelectric actuator according to the present invention uses a piezoelectric element which is small in size and large in generative force as a driving source so that a bending displacement is generated, and a member to be driven is supported at a point where an angular displacement thereof is maximum, or a force couple is given to a support point of the member to be driven to obtain a large displacement. In addition, the driving mechanism is structured by a combined mechanism that can be rotatably driven with respect to two axes that cross each other, to realize a mechanism that is capable of directing the member to be driven in a desired direction.

### BACKGROUND OF THE INVENTION

1. Field of the Invention

The present invention relates to an actuator having an optical path change-over function and an adjusting function used in an optical communication field, an information recording device or the like.

2. Description of the Related Art

As shown in FIG. 1, an optical switch used in the optical communication field intervenes between one optical fiber group having a plurality of channels and another optical fiber group having a plurality of channels, and has a function of switchingly inputting a light emitted from an end portion of each of optical fibers in the one optical fiber group to an end portion of each of optical fibers in the other optical fiber group. The optical switch thus structured is roughly classified into four systems consisting of a mechanical type, a plane optical waveguide type, a mirror type and a bubble type. The recent optical communication field requires a large-scaled optical switch which is applicable to multiple waveguides that exceed several hundreds of channels, and attention is paid to the mirror type because this type can deal with the multiple waveguides. The mirror type is a type in which an incident light from the optical fiber is reflected by a fine mirror using a silicon substrate or the like to change an optical path. In the mirror type, the mirror is displaced to allow the reflection or transmission of the light, or a direction of the mirror is changed to alter an outgoing direction of the reflected light. The mirror type is advantageous as a compact multiple channel change-over optical switch in that a light can be switchably outputted to a plurality of channels by changing the direction of one mirror.

By the way, there is an example in which an electrostatic actuator is employed in the driving of the channel optical switch of this type. The electrostatic actuator is so designed as to drive a mirror member by applying an electrostatic voltage while changing over from a normal voltage to a reverse voltage. However, because of the use of an electrostatic force, there arises such a problem that not only the electrostatic actuator is improper for a large-load drive because the driving force is weak, but also the electrostatic actuator is weak with respect to a disturbance such as vibrations, requires an extremely large drive voltage and is liable to be influenced by humidity.

### SUMMARY OF THE INVENTION

The present invention has been made to solve the above drawbacks, and therefore an object of the present invention is to provide an actuator that has a compact structure and a large driving force and is not affected by a disturbance such as vibrations and environmental conditions such as temperature or humidity.

To achieve the above object, according to the present invention, there is provided a piezoelectric actuator which uses a piezoelectric element which is small in size and large in generative force as s driving source so that a bending displacement is generated, and a member to be driven is supported at a point where an angular displacement thereof is maximum, or a force couple is given to a support point of the member to be driven to obtain a large displacement. In addition, the driving mechanism is structured by a combined mechanism that can be rotatably driven with respect to two axes that cross each other, to realize a mechanism that is capable of directing the member to be driven in a desired direction.

### BRIEF DESCRIPTION OF THE DRAWINGS

These and other objects and advantages of this invention will become more fully apparent from the following detailed description taken with the accompanying drawings in which:

FIG. 1 is a diagram showing a combination of fiber arrays on an output side and a light receiving side which is used in an optical communication;

FIG. 2 is a diagram showing a mirror type optical switch between fiber arrays on the output side and the light receiving side;

FIG. 3 is a diagram showing a lens type optical switch between fiber arrays on the output side and the light receiving side;

FIGS. 4A and 4B are diagrams for explaining piezoelectric members of a bimorph type and a unimorph type;

FIGS. 5A to 5C are diagrams for explaining a mechanism that generates a force couple;

FIGS. 6A and 6B are diagrams showing examples of an actuator using a plurality of piezoelectric members;

FIGS. 7A to 7E are diagrams showing examples of actuators that generate a bending motion in the piezoelectric member;

FIG. 8 is a diagram showing an example of an actuator which enables two-axial driving by using an actuator that generates the bending motion in two pairs of piezoelectric members and a frame;

FIGS. 9A and 9B are diagrams showing examples of a piezoelectric member in which two pairs of piezoelectric members that conduct warp movement are joined together in parallel and which generates a twist motion with the joint portion used as a shaft, and an actuator that enables two-axial driving by using two pairs of piezoelectric members with a frame, respectively;

FIGS. 10A and 10B are diagrams showing examples of an actuator that enables two-axial driving by using two pairs of frames each of which is formed by using a piezoelectric member per se; and

FIGS. 11A to 11C are diagrams showing support mechanism examples according to the present invention.

### DETAILED DESCRIPTION OF THE PREFERRED EMBODIMENTS

Now, a description will be given in more detail of preferred embodiments of the present invention with reference to the accompanying drawings.

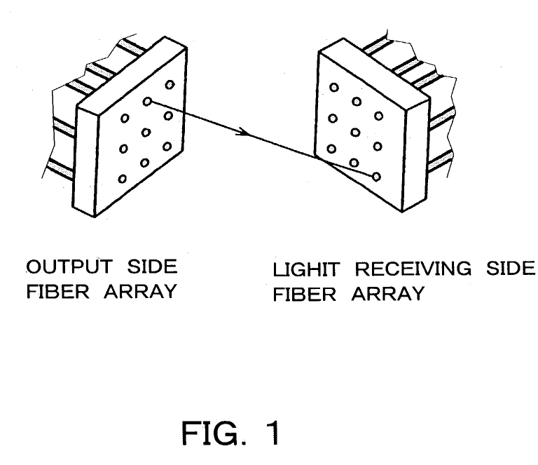

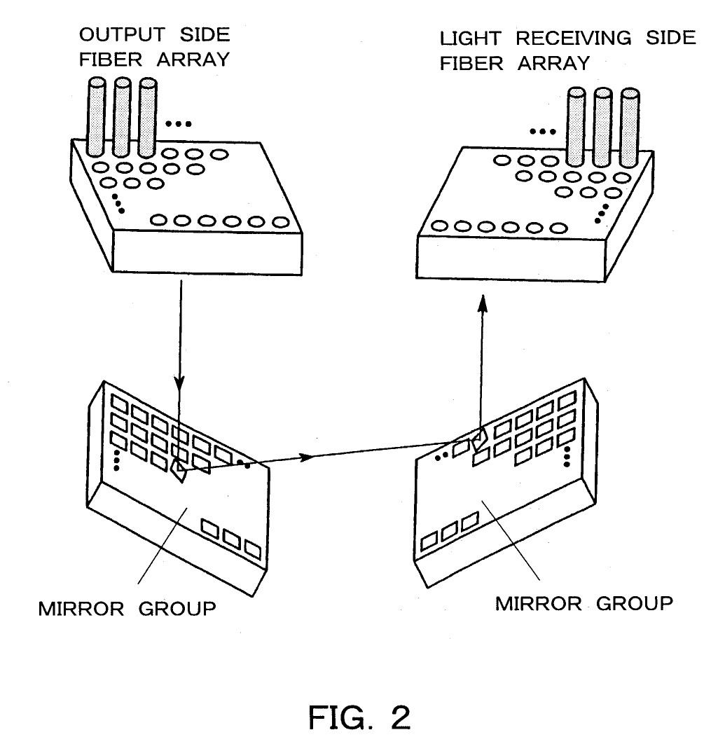

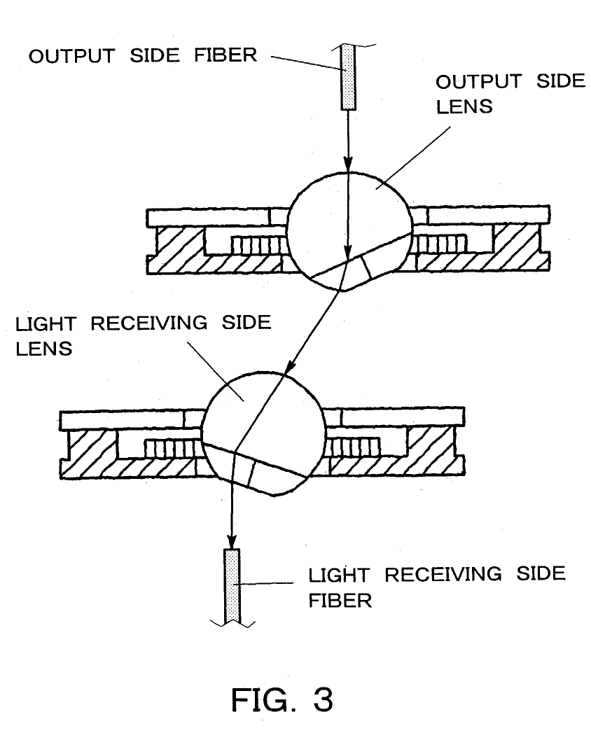

The present invention derives from the development and provision of an optical switch that is capable of surely conducting the change-over of multiple channels required in the optical communication field with a compact structure. As an optical switch that lies between one optical fiber group having a plurality of channels and another optical fiber group having a plurality of channels, and has a function of switchingly inputting a light emitted from an end portion of each of optical fibers in the one optical fiber group to a desired end portion of optical fibers in the another optical fiber group as shown in FIG. 1, the present invention uses a plurality of mirrors as shown in FIG. 2 and a plurality of lenses as shown in FIG. 3. As other means for changing a direction of an optical path, an optical device such as a fiber or a prism can be selectively employed in the present invention.

An optical switch shown in FIG. 2 includes a plurality of output fiber arrays and a plurality of light receiving fiber arrays which are arranged in plural matrices longitudinally and laterally, and two mirror arrays in addition. After a light outputted from the output fiber arrays is reflected by a first mirror array and then reflected by a second mirror array, the light is inputted to the light receiving fiber arrays. The adjustment of an angle of each mirror in those two mirror arrays makes it possible to input the output light from the output fiber array to a fiber of an arbitrary port of the light receiving fiber array. Also, an optical switch shown in FIG. 3 is so structured as to direct an output light to a fiber of an arbitrary port by variably setting the angles of lenses disposed on the end surface of the respective output fibers and lenses disposed on the end surfaces of the respective light receiving fibers, and to receive the incident light without any loss. The structure using the output fiber arrays and the light receiving fiber arrays which are arranged in plural matrices longitudinally and laterally as described above makes it possible to realize a switch that is small in loss even if the switch is large-scaled because a spatial distance where the light is emitted can be made extremely short.

Incidentally, the optical switch is required to lie between the output fiber arrays and the light receiving fiber arrays and to drive and control an optical device that changes the direction of the optical path in a desired direction. As a means for satisfying that requirement, the present invention uses a piezoelectric element which is small in size and large in generative force as a driving source. The present invention provides a mechanism in which a bending displacement is generated by the piezoelectric element, and a member to be driven is supported at a point where an angular displacement thereof is maximum, a force couple is given to a support point of the member to be driven to obtain a large displacement, or there is used a mechanism that is so designed as to be rotatably driven with respect to two axes that cross with each other, generally two axes that are orthogonal to each other in combination, to thereby realize a mechanism that is capable of directing the member to be driven in a desired direction. Hereinafter, various embodiments of the actuator using the piezoelectric element will be described sequentially.

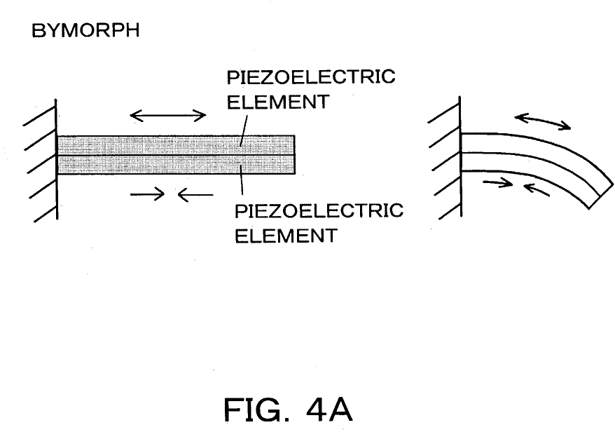

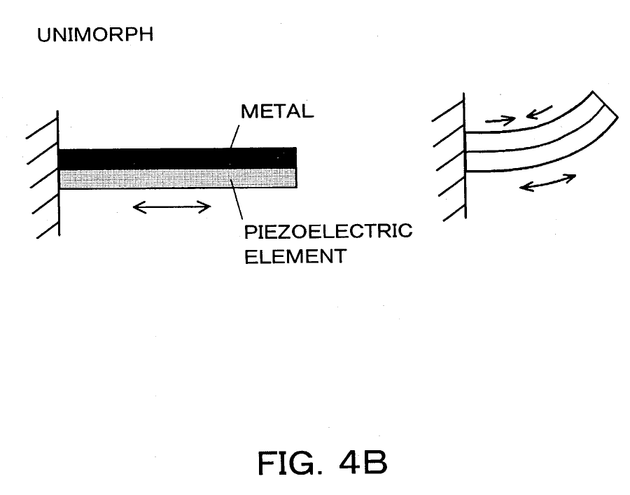

A basic form of an actuator using a piezoelectric element is shown in FIGS. 4A and 4B. FIG. 4A shows a bimorph type in which two strip-shaped piezoelectric elements that expand and contract in longitudinal direction are superimposed on each other. In the bimorph type, those piezoelectric elements are differentially expanded or contracted by reversely applying a voltage to the respective piezoelectric elements so that one piezoelectric element expands and the other piezoelectric element contracts as shown on a right side of the figure, to thereby warp those piezoelectric elements vertically in the form of a bimetal. FIG. 4B shows a unimorph type in which one strip-shape piezoelectric element is affixed on a metal in which the piezoelectric element is expanded or contracted due to normal and reverse voltages by applying the voltages to the piezoelectric element. Since the metal is neither expanded nor contracted, the piezoelectric element and the metal change relatively in length, and the piezoelectric element and the metal warp vertically in the form of a bimetal as shown on the right side of the figure. If one end of the member is fixed, the other end is displaced in accordance with the bending. The displacement of the member is utilized as a driving force.

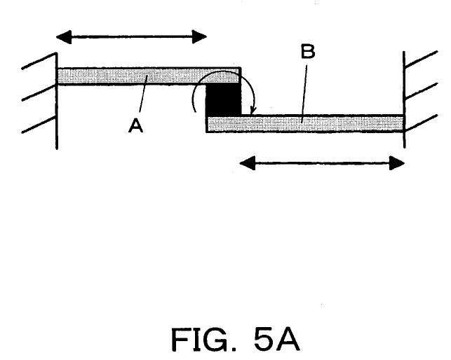

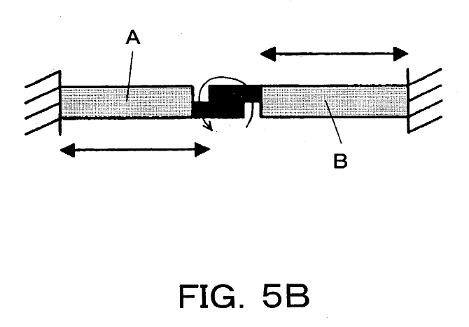

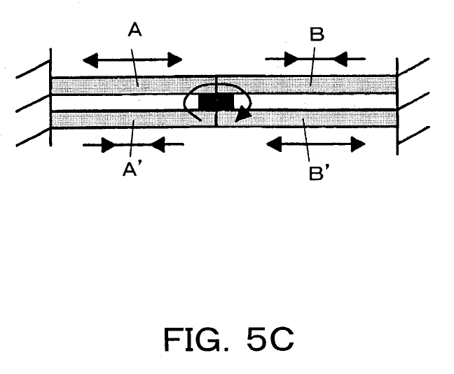

Subsequently, FIGS. 5A, 5B and 5C show actuators that directly use the axial expanding and contracting movement of a rod-shaped piezoelectric element. FIG. 5A shows an actuator in which a piezoelectric member A having one end fixed and a piezoelectric member B having one end fixed are connected to different portions of a member to be driven at the other ends thereof, and a force couple is generated in the member to be driven by the expanding operation of both the piezoelectric members A and B. FIG. 5B shows an actuator in which a piezoelectric member A having one end fixed and a piezoelectric member B having one end fixed are connected to both end portions of a Z-shaped member to be driven at the other ends thereof, and a force couple is generated in the member to be driven by the expanding operation of both the piezoelectric members A and B. FIG. 5C shows an actuator in which a piezoelectric member A having one end fixed and a piezoelectric member A′ having one end fixed are disposed in parallel with each other and hold a member to be driven therebetween at the other ends thereof, and in a symmetric form with this, a piezoelectric member B having one end fixed and a piezoelectric member B′ having one end fixed are disposed in parallel with each other and hold the member to be driven therebetween at the other ends thereof. The operation is made in such a manner that the piezoelectric member A′ is contracted when the piezoelectric member A is expanded, and the piezoelectric member B′ is expanded while the piezoelectric member B is contracted. That is, the operation is made in such a manner that the piezoelectric members A, A′ and the piezoelectric members B, B′ are always reverse in expansion and contraction, and the piezoelectric members A, B′ and the piezoelectric members A′, B are always identical in expansion and contraction. This operation generates a force couple in the member to be driven.

Actuators using the piezoelectric element in accordance with various embodiments will be described sequentially.

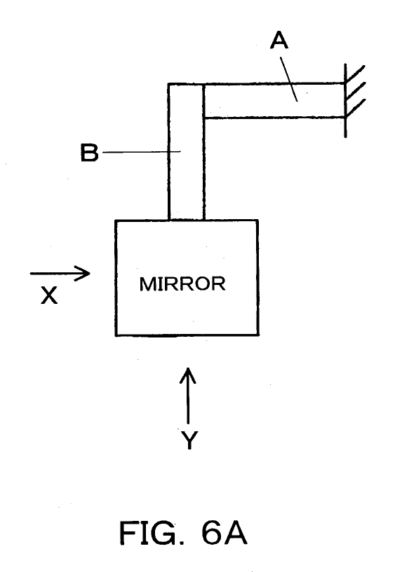

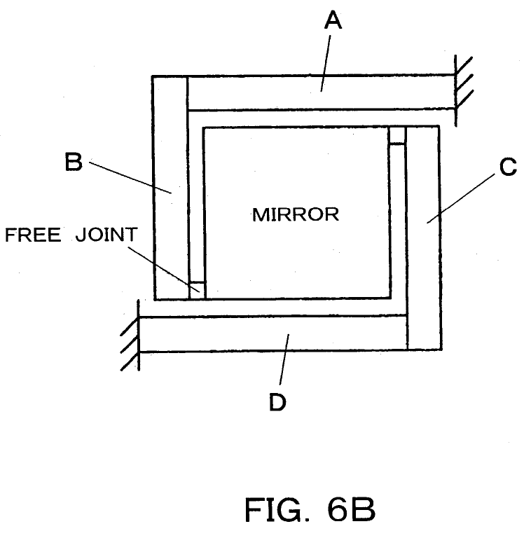

FIG. 6A shows an actuator in which one unimorph or bimorph strip-shaped piezoelectric member A having one end fixed has the other end to which one end of another unimorph or bimorph strip-shaped piezoelectric member B having a different longitudinal direction from that of the piezoelectric member A is attached. According to this structure, the other end portion of the piezoelectric member B has a displacement resulting from composing a displacement amount of the other end of the piezoelectric member A with a displacement amount of the piezoelectric member B. For example, the other end of the piezoelectric member A having one end fixed is displaced in the front and back surface directions of the figure, and when the other end of the piezoelectric member A is displaced toward the back surface side by applying a voltage, a mirror fixed on the other end of the piezoelectric member B rotates counterclockwise when being viewed from a Y-direction in the figure. The piezoelectric member B is also displaced in the front and back surface directions of the figure, and when the piezoelectric member B is displaced toward the front surface side by applying a voltage, a mirror fixed on the other end of the piezoelectric member B rotates counterclockwise when being viewed from a X-direction in the figure. A free movement is given to the mirror by controlling those two displacements, independently.

FIG. 6B shows an actuator in which two actuators structured as shown in FIG. 6A are combined together. In this example, a mirror is shown as a member to be driven, and different portions of the mirror are connected to the respective end portions of the piezoelectric elements A and B, and the mirror changes its direction by the displacements of the two support portions according to the respective movements of those four piezoelectric members. It is preferable that the support portions are formed of a free joint such as a ball and socket joint so that the mirror can face toward any directions. However, in the case of manufacturing a downsized actuator, it is acceptable that an elastic material that is low in rigidity is used as the free joint. With this structure, there is applied a manufacturing method in which an elastic portion having a given shape that also serves as a metal portion of a unimorph or an intermediate electrode of a bimorph is formed, for example, by etching, and a piezoelectric member is then manufactured through a sol-gel method, a sputtering method or the like.

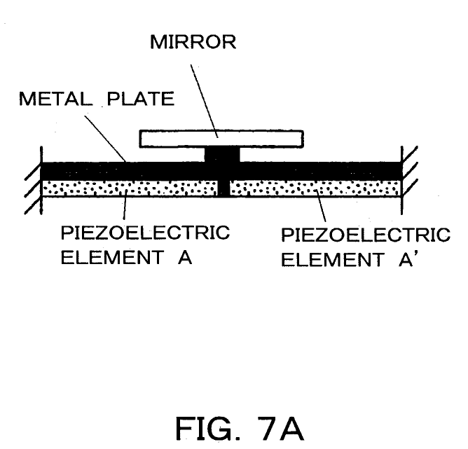

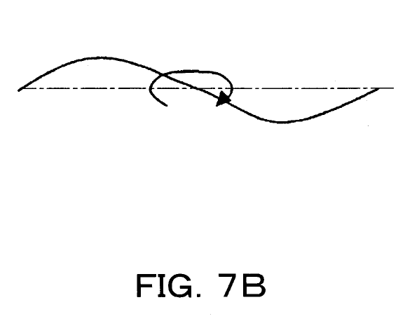

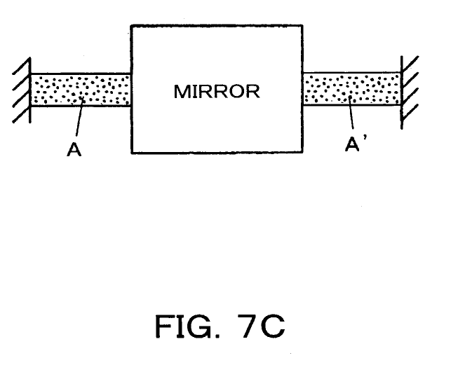

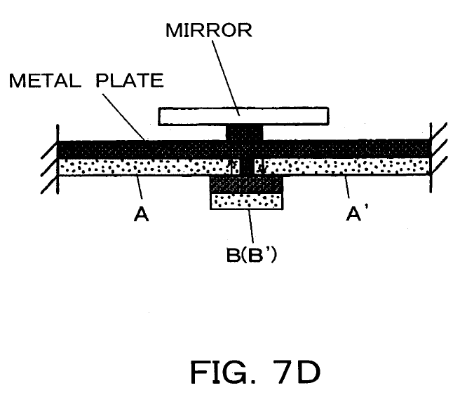

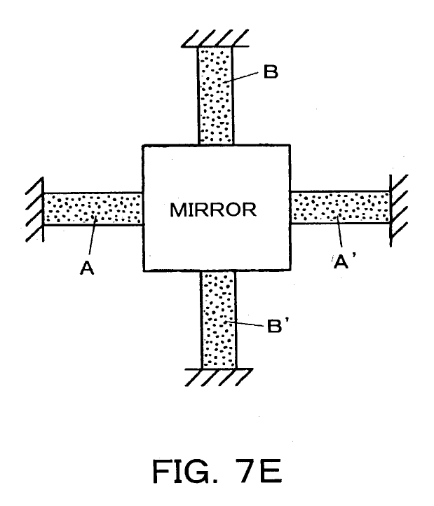

FIGS. 7A to 7E show an embodiment in which two strip-shaped piezoelectric members A and A′ of the unimorph or bimorph are connected to each other in the longitudinal direction. In the embodiment, both ends of the connected piezoelectric members are fixed, both of the piezoelectric members are warped in a reverse direction, and a twist movement is generated on a joint portion at which both of the piezoelectric members are connected to each other. FIG. 7A shows a laterally cross-sectional view of the unimorph system, and FIG. 7C shows a plan view thereof in which a mirror is mounted on the joint portion at a center thereof. As shown in FIG. 7B, when a voltage is applied to the piezoelectric member A to generate a convex warp and a voltage is applied to the piezoelectric member A′ to generate a concave warp, the joint portion generates the twist movement as indicated by an arrow so that the mirror is brought into a right down state. When an applied voltage is reversed, the piezoelectric member A is warped in a concave shape, and the piezoelectric member A′ is warped in a convex shape so that the mirror comes to a left down state. In other words, a bending displacement occurs with the joint portion as a node as a whole.

FIGS. 7D and 7E show embodiments in which the above-mentioned mechanisms are combined together in a different direction, in this example, in an orthogonal direction. FIG. 7D is a laterally cross-sectional view and FIG. 7E is a plan view. According to this structure, a bending displacement is generated by the piezoelectric members A and A′ so that the mirror on the center portion can be inclined, and the similar bending displacement is generated by the piezoelectric members B and B′ even in the different direction so that the center portions of the piezoelectric members A and A′ are inclined in the different direction on the center portion, and a composed inclined displacement of both the mechanisms can be given to the mounted mirror.

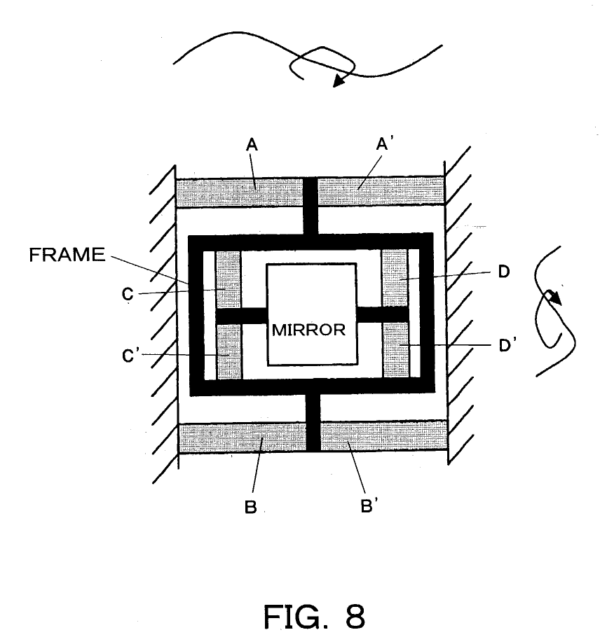

FIG. 8 shows an embodiment in which the above-mentioned mechanisms are combined together in a different direction, generally in an orthogonal direction. First, the shafts of a frame are fixed to the joint portions of piezoelectric members A, A′ and piezoelectric members B, B′ which are fixed to fixed portions of both sides thereof, and piezoelectric members C, C′ and piezoelectric members D, D′ each having a mechanism shown in FIG. 6 are arranged in a direction different from that of the above piezoelectric elements A, A′ and B, B′ within the frame, and shafts that fix a member (mirror) to be driven at a center thereof are fixed to the joint portions of those piezoelectric elements C, C′ and D, D′, respectively. In the combination of the piezoelectric members, the piezoelectric members A and B, the piezoelectric members A′ and B′, the piezoelectric members C and D, and the piezoelectric members C′ and D′ are so structured as to conduct the same warp operation, respectively. Assuming that a voltage is applied to the piezoelectric member so that the piezoelectric members A and B are warped in the convex shape and the piezoelectric members A′ and B′ are warped in the concave shape, the frame is inclined downward toward the right direction. Then, as shown in the figure, when the piezoelectric members C and D are warped so that the front surface sides thereof become convex, and the piezoelectric members C′ and D′ are warped so that the back surface sides thereof become convex, the mirror is inclined toward the front side as in the bowing manner within the frame that is inclined downward toward the right direction. Thus, with the combination of the twist motions in the different directions through the frame, the position of the member to be driven can be controlled in any directions.

Also, it is easily understandable that the mechanism shown in FIG. 8 can be also realized by employing a piezoelectric actuator that generates a force couple directly utilizing an expansion and contraction force of the piezoelectric element shown in FIG. 5.

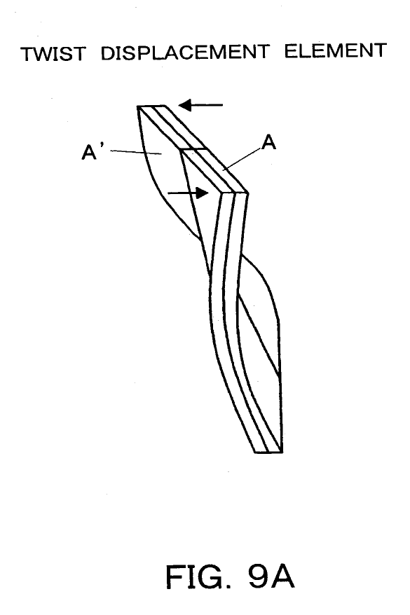

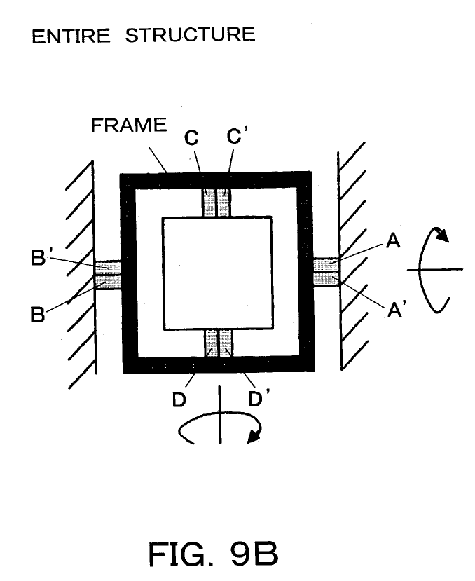

Subsequently, a piezoelectric member having a different twist form is shown in FIGS. 9A and 9B. The twist displacement element is structured in such a manner that two strip-shaped piezoelectric members A and A′ of a unimorph or a bimorph are arranged in parallel with each other in the longitudinal direction and connected to each other as shown in FIG. 9A. A voltage is applied to the piezoelectric members A and A′ so that both one end sides of those piezoelectric members are fixed, and the piezoelectric members A and A′ are warped in the reverse direction in such a manner that one piezoelectric member A becomes convex at the left side, and the other piezoelectric member A′ becomes convex at the right side. In this case, the other end side of the piezoelectric member A is going to be displaced clockwise in the figure, and the other end side of the piezoelectric member A′ is going to be displaced counterclockwise. However, because both of those members A and A′ are joined together at their side surfaces, both forces of those members cancel each other at the center portions of the other ends thereof, and a corner portion at the other end side of the piezoelectric member A is displaced toward the right side in the figure, and a corner portion at the other end side of the piezoelectric member A′ is displaced toward the left side in the figure. That is, the other ends of both the members A and A′ generate the twist motions counterclockwise when being viewed from the upper. Also, in this embodiment, if the polarization directions of the piezoelectric member A and the piezoelectric member A′ are made different from each other, the twist motion can be generated by the supply voltage in the same direction. In this case, various displacements of the respective piezoelectric members are restricted, but an electrode is made common and the supply voltage is also made identical so that simplification can be performed.

Also, in the form shown in FIG. 9B, the twist displacement element mechanisms are combined, generally combined in a direction in which they are orthogonal to each other. First, one end of the piezoelectric members A, A′ is fixed to a fixing portion and at the same time, one end of the similar piezoelectric members B, B′ is fixed to another fixing portion. The other ends of both members are fixed to the center portions of the frame which are opposite to each other, respectively. Further, the piezoelectric members C, C′ and the similar piezoelectric members D, D′, which both have the mechanism shown in FIG. 9A, are arranged such that one ends thereof are fixed to the frame at positions at which they are opposite to each other in a different direction of the above piezoelectric members. Further, the other ends of both members are used to fix the opposite sites of the driving member (mirror). Also, the piezoelectric members are combined such that the piezoelectric members A, A′ and the piezoelectric members B, B′ are equal to each other in the direction of the twist operation as well as the piezoelectric members C, C′ and the piezoelectric members D, D′ are equal to each other in the direction of the twist operation. Here, when the voltage is applied to the piezoelectric members that are arranged as shown in the figures, the frame is slanted to the right. When the piezoelectric members A, A′ and the piezoelectric members B, B′ are twisted clockwise in a vertical direction as shown in the figures, the frame rotates in the form of being curved backward in the figures. Then, when the piezoelectric members C, C′ and the piezoelectric members D, D′ move clockwise in a horizontal direction as shown in the figures, the mirror is slanted to the right in the frame slanted in the form of being curved backward. In this way, the twist movements in different directions are combined through the frame, so that the member to be driven can be controlled in posture in all directions.

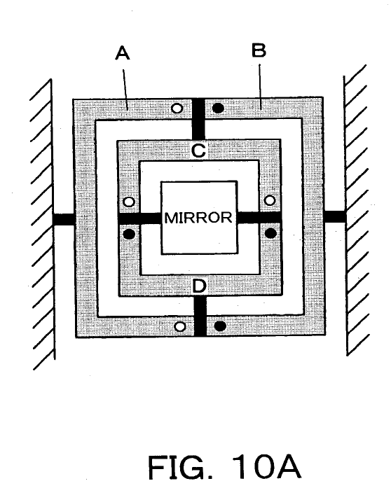

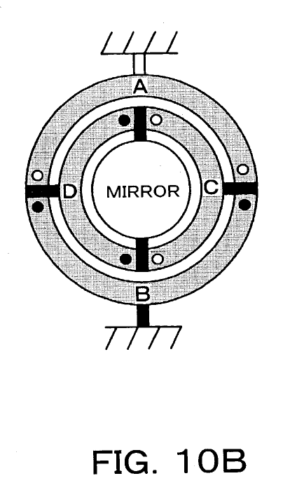

Still further embodiments in which a frame that supports a member to be driven (mirror) is structured by two pair of piezoelectric members that are different in displacement directions are shown in FIGS. 10A and 10B. FIGS. 10A and 10B show a structure in which a pair of U-shaped unimorph and bimorph type piezoelectric members A and B have both ends connected to each other so as to be shaped in a ring, and the center portions of both the members A and B that face each other are fixed to fixing members through shaft members, respectively. Also, in the structure, another pair of U-shaped unimorph and bimorph type piezoelectric members C and D have both ends connected to each other so as to be shaped in a ring, and the center portions of both the members C and D that face each other are fixed to joint portions of the piezoelectric members A and B through shaft members, respectively, to form an inner frame. Shafts at both end portions of a member to be driven (mirror) are attached to the joint portions of the inner frame. FIG. 10A shows a rectangular type in which a U-shape is square, and FIG. 10B shows a round type in which the U-shape is semi-circular, which are fundamentally identical with each other. Since the piezoelectric members A, B and the piezoelectric members C, D are structured in such a manner that the warps of those members become reverse to each other by applying a voltage, a twist force is exerted on each of the joint portions of those members. In FIG. 10A, when a force is exerted on those piezoelectric members so that both end portions of the piezoelectric member A having the center portion fixed are warped toward the front surface side in the figure (indicated by ∘), and both end portions of the piezoelectric member B having the center portion fixed are warped toward the back surface side in the figure (indicated by ●), the shafts connected to the joint portions are rotatably displaced in such a manner that the right side of the shaft moves to the back side and the left side of the shaft moves to the front side. The rotational displacement allows the ring of the piezoelectric members C and D which structure the inner frame to be inclined downward toward the right direction. The ring of the piezoelectric members C and D is also deformed by applying a voltage, for example, both end portions of the piezoelectric member C are warped toward the front side in the figure, and when a force is applied to the piezoelectric member B so that both end portions of the piezoelectric member B having the center portion fixed is warped toward the back side in the figure, the shafts to which the mirror is fixed are warped in such a manner that the upper side of the shaft is warped toward the front side and the lower side of the shaft is warped toward the back side, and the shaft rotates as in the bowing manner. It is needless to say that if the direction of the applied voltage changes, the drive is reversed.

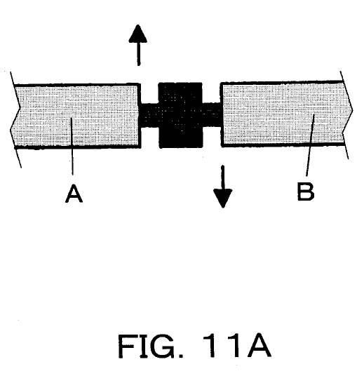

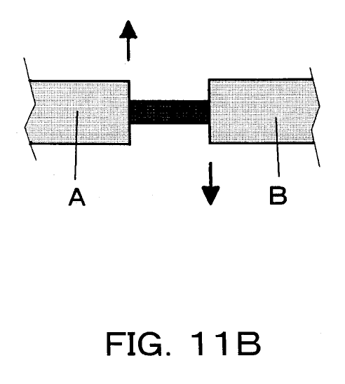

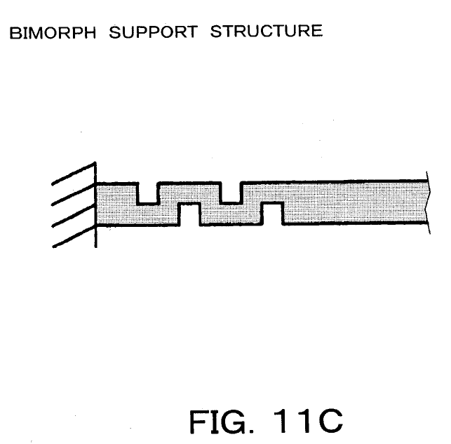

FIGS. 11A to 11C show examples of the support form of the member in accordance with the present invention. The example shown in FIG. 11A is applied to an actuator in which the right and left piezoelectric members A and B are warped in the vertical directions reverse to each other in the paper. The member to be driven is supported by a member thinner than the piezoelectric members at the centers of the free end portions of both the piezoelectric members so as to be sandwiched from both sides thereof. When the rotational force occurs in a direction indicated by an arrow, the members A and B to be driven in the center are rotatably driven clockwise, and in this situation, the thin and low-rigid support portion performs the conversion function that allows a large rotational displacement without obstructing the movement of the members to be driven A and B. The example shown in FIG. 10B is applied to an actuator in which the right and left piezoelectric members A and B are warped in the vertical directions reverse to each other in the paper, and the free end center portions of both the piezoelectric members are coupled to each other by a member thinner than the piezoelectric members. When the force is exerted in a direction indicated by an arrow, the piezoelectric member A is going to be displaced upward whereas the piezoelectric member B is going to be displaced downward. In this situation, the support portion which is thin and low in rigidity performs the conversion function that allows the large rotational displacement without obstructing the movement thereof. As a result, the thin center coupling member is inclined downward in the right direction, and when the member to be driven is stuck onto the thin member, the downward inclination in the right direction is transmitted to the member to be driven. The example shown in FIG. 11C shows a fixed end side structure of the piezoelectric member of the bimorph or the unimorph type in which both ends of the piezoelectric members are supported. For example, the piezoelectric member (not shown) is supported by a support portion having a structure in which notch grooves are alternately defined. With this structure, the restraint at both end portions of the bimorph type or unimorph type piezoelectric member is eliminated, and the vertical deformation is increased. The grooves may be formed not in both sides as shown in the figure, but in one side, and a notch may be formed not in the thickness direction but in the widthwise direction.

The piezoelectric actuators according to various embodiments were described above. The present invention has been made aiming at the development and provision of an optical switch at its initial stage, which is capable of surely conducting the change-over operation on the multiple channels required in the optical communication field with a compact structure, and the optical switch has been developed to purpose to obtain the actuator that drives the optical device such as a mirror which is applied to the optical switch. However, it is apparent that the piezoelectric actuator is not limited to the above, but is applicable as the actuators of various devices such as a driver or an adjustor of an optical pickup for a CD, a DVD or the like, and an application thereof is not limited to the optical switch.

As was described above, according to the piezoelectric actuator of the present invention, since the piezoelectric element that is small in size and large in generative force is used as a driving source, so that a bending displacement is generated, and a member to be driven is supported at a point where an angular displacement thereof is maximum, or a force couple is given to a support point of the member to be driven to obtain a large displacement. Therefore, the present invention can provide an actuator that has a compact structure and a large driving force and is not affected by a disturbance such as vibrations and environmental conditions such as temperature or humidity.

As specific structures of the piezoelectric actuator, the piezoelectric actuator includes: a first piezoelectric member which is partially fixed and displaced in a first direction; and a second piezoelectric member which is connected to the first piezoelectric member and displaced in a second direction, which drives a member to be driven which is fixed to the second piezoelectric member. Such an actuator can compose the movements of those two piezoelectric members so as to be widely adapted to a desired drive. In addition, the piezoelectric actuator including two pairs of piezoelectric actuators as described above, which drives the member to be driven which is supported to the respective second piezoelectric members, has a function of directing the member to be driven in a desired direction and stably supporting the member to be driven.

Also, in the piezoelectric actuator according to the present invention, two piezoelectric members with a unimorph or bimorph structure are flush with each other and formed integrally with each other, and one end of the integrally formed members is fixed and the other end thereof is fixed with the member to be driven, and the two piezoelectric members are displaced in the reverse directions so that the piezoelectric actuator having a boundary between those piezoelectric members as a rotary axis can generate a twist displacement which is high in driving force while the piezoelectric actuator is small in size.

Also, according to the present invention, the piezoelectric actuator adopts a structure in which a bending displacement is generated in a strip-shaped piezoelectric member having both ends fixed with both end portions and the center portion thereof used as nodes, and the member to be driven is supported on a boundary at which a direction of bending displacement is reversed, thereby being capable of rotatably driving the member to be driven in the direction of bending displacement.

Also, according to the present invention, the piezoelectric actuator adopts a structure in which at least two pairs of rod-shaped piezoelectric members that have one ends thereof fixed and conduct the expansion and contraction operation in the longitudinal direction are used, and the other ends of those piezoelectric members are connected to different portions of the member to be driven, thereby being capable of giving a force couple to the member to be driven.

Also, according to the present invention, the piezoelectric actuator adopts a structure in which two strip-shaped piezoelectric members of the unimorph or bimorph are arranged in parallel with each other in a longitudinal direction and connected to each other, and one end sides thereof are fixed, and a voltage is applied to those piezoelectric members so that the warps of those piezoelectric members become reverse to each other in such a manner that one piezoelectric member becomes convex and the other piezoelectric member becomes concave, to thereby produce a twist motion at the other ends of those members. In addition, the piezoelectric actuator adopts a structure in which the piezoelectric actuator according to one of third to sixth aspects of the present invention takes a combined mechanism that can be rotatably driven with respect to two shafts that cross each other, thereby being capable of realizing a mechanism of directing the member to be driven in a desired direction.

Also, according to the present invention, the piezoelectric actuator adopts a structure in which one pair of U-shaped unimorph or bimorph type piezoelectric members have both ends connected to each other into a ring shape, and the center portions of both the members that face each other are fixed to fixing members through shaft members, respectively, and another pair of U-shaped unimorph or bimorph type piezoelectric members have both ends connected to each other into a ring shape, and the center portions of both the members that face each other are fixed to joint portions of the above piezoelectric members through shaft members, respectively, to form an inner frame, and shafts at both end portions of a member to be driven are attached to the joint portions of the inner frame. This structure uses the piezoelectric member not as the structure of the driving portion but as the structure of the frame, whereby the structure is advantageous in the small-size and large-output specification of the mechanism.

The piezoelectric actuator according to the present invention is effective in the drive of an electronic device having an optical device such as a mirror, a lens, a fiber or a prism which determines the optical path direction of the optical switch because the piezoelectric actuator is large in driving force with a compact structure and is not affected by the disturbance such as vibrations and the environmental conditions such as temperature or humidity.

The foregoing description of the preferred embodiments of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto, and their equivalents.

What is claimed is:

1. A piezoelectric actuator, comprising:
a first piezoelectric member which is partially fixed and displaced in a first direction;
a second piezoelectric member which is connected to the first piezoelectric member and displaced in a second direction, the piezoelectric actuator driving a member to be driven which is fixed to the second piezoelectric member.

2. A piezoelectric actuator, comprising two pairs of piezoelectric actuators as claimed in claim 1, wherein the piezoelectric actuators drive members to be driven which are supported by respective second piezoelectric members.

3. A piezoelectric actuator in which two piezoelectric members with a unimorph or bimorph structure are flush with each other and formed integrally with each other, and one end of the integrally formed members is fixed and the other end thereof is fixed to a member to be driven, and in which the two piezoelectric members are displaced in reverse directions to give a twist displacement to the member to be driven with a boundary between the two piezoelectric members used as a rotary axis.

4. A piezoelectric actuator in which a bending displacement is generated in a strip-shaped piezoelectric member having both ends fixed, and the driving portion is supported on a boundary at which a direction of the bending displacement is reversed, and a member to be driven is rotatably driven in a direction of the bending displacement.

5. A piezoelectric actuator comprising at least two pairs of rod-shaped piezoelectric members that have one ends thereof fixed and conduct expansion and contraction operation in a longitudinal direction, the other ends of the piezoelectric members being connected to different portions of a member to be driven to give a force couple to the member to be driven.

6. A piezoelectric actuator comprising:
two strip-shaped piezoelectric members of unimorph or bimorph which are arranged in parallel with each other in a longitudinal direction and connected to each other, wherein one end sides thereof are fixed, and a voltage is applied to the piezoelectric members so that warps of the piezoelectric members become reverse to each other in such a manner that one piezoelectric member becomes convex and the other piezoelectric member becomes concave, to produce a twist motion at the other ends of the piezoelectric members.

7. A piezoelectric actuator in which a frame is driven by the piezoelectric actuator as claimed in claim 3, and a piezoelectric actuator which is different in a rotational direction from the piezoelectric actuator and has the same type as that of the piezoelectric actuator is attached onto the frame, to allow a member to be driven which is attached to the piezoelectric actuator to rotate about different two axes.

8. A piezoelectric actuator in which a frame is driven by the piezoelectric actuator as claimed in claim 4, and a piezoelectric actuator which is different in a rotational direction from the piezoelectric actuator and has the same type as that of the piezoelectric actuator is attached onto the frame, to allow a member to be driven which is attached to the piezoelectric actuator to rotate about different two axes.

9. A piezoelectric actuator in which a frame is driven by the piezoelectric actuator as claimed in claim 5, and a piezoelectric actuator which is different in a rotational direction from the piezoelectric actuator and has the same type as that of the piezoelectric actuator is attached onto the frame, to allow a member to be driven which is attached to the piezoelectric actuator to rotate about different two axes.

10. A piezoelectric actuator in which a frame is driven by the piezoelectric actuator as claimed in claim 6, and a piezoelectric actuator which is different in a rotational direction from the piezoelectric actuator and has the same type as that of the piezoelectric actuator is attached onto the frame, to allow a member to be driven which is attached to the piezoelectric actuator to rotate about different two axes.

11. A piezoelectric actuator in which: one pair of U-shaped unimorph or bimorph type piezoelectric members have both ends connected to each other into a ring shape, center portions of the pair of piezoelectric members that face each other being fixed to fixing members through shaft members, respectively; and
another pair of U-shaped unimorph or bimorph type piezoelectric members have both ends connected to each other into a ring shape, center portions of the other pair of piezoelectric members that face each other being fixed to joint portions of the one pair of piezoelectric members through shaft members, respectively, to form an inner frame, in which shafts at both end portions of a member to be driven are attached to the joint portions of the inner frame.

12. An electronic device with the piezoelectric actuator as claimed in claim 1, wherein a member to be driven comprises an optical device selected from the group consisting of a mirror, a lens, a fiber and a prism which determines an optical path direction.

13. An electronic device with the piezoelectric actuator as claimed in claim 2, wherein a member to be driven comprises an optical device selected from the group consisting of a mirror, a lens, a fiber and a prism which determines an optical path direction.

14. An electronic device with the piezoelectric actuator as claimed in claim 3, wherein a member to be driven comprises an optical device selected from the group consisting of a mirror, a lens, a fiber and a prism which determines an optical path direction.

15. An electronic device with the piezoelectric actuator as claimed in claim 4, wherein a member to be driven comprises an optical device selected from the group consisting of a mirror, a lens, a fiber and a prism which determines an optical path direction.

16. An electronic device with the piezoelectric actuator as claimed in claim 5, wherein a member to be driven comprises an optical device selected from the group consisting of a mirror, a lens, a fiber and a prism which determines an optical path direction.

17. An electronic device with the piezoelectric actuator as claimed in claim 6, wherein a member to be driven comprises an optical device selected from the group consisting of a mirror, a lens, a fiber and a prism which determines an optical path direction.

18. An electronic device with the piezoelectric actuator as claimed in claim 7, wherein a member to be driven comprises an optical device selected from the group consisting of a mirror, a lens, a fiber and a prism which determines an optical path direction.

19. An electronic device with the piezoelectric actuator as claimed in claim 8, wherein a member to be driven comprises an optical device selected from the group consisting of a mirror, a lens, a fiber and a prism which determines an optical path direction.
